(19) United States
(12) Patent Application Publication
(10) Pub. No.: US 2023/0154963 A1
(43) Pub. Date: May 18, 2023

(54) PHOTOELECTRIC CONVERSION DEVICE, PHOTOELECTRIC CONVERSION SYSTEM, AND MOVING BODY

(71) Applicant: CANON KABUSHIKI KAISHA, Tokyo (JP)

(72) Inventors: Hideo Kobayashi, Tokyo (JP); Yu Katase, Kanagawa (JP)

(21) Appl. No.: 17/981,657

(22) Filed: Nov. 7, 2022

(30) Foreign Application Priority Data
Nov. 12, 2021 (JP) 2021-185153

(51) Int. Cl. H01L 27/146

(52) U.S. Cl. CPC H01L 27/14636; H01L 27/14603; H01L 27/14634

(57) ABSTRACT

A photoelectric conversion device includes a structure in which first and second substrates are stacked. The first substrate includes pixels, first vertical signal lines extending parallel to a first direction, and first joints respectively electrically connected to the first vertical signal lines. The second substrate includes second joints respectively electrically connected to the first joints, second vertical signal lines arranged so as to extend parallel to the first direction, column circuits respectively electrically connected to the second vertical signal lines, connecting lines respectively electrically connected to the second joints, and extending parallel to a second direction orthogonal to the first direction, and an interlayer connection configured to electrically connect each of the second vertical signal lines and the corresponding connecting line of the connecting lines.

### BACKGROUND OF THE INVENTION

### Field of the Invention

The present invention relates to a photoelectric conversion device, a photoelectric conversion system, and a moving body.

### Description of the Related Art

Japanese Patent Laid-Open No. 2020-78020 describes a solid-state image capturing device that includes at least two column regions for A/D-converting pixel signals generated in pixels, a plurality of vertical signal lines for transferring the pixel signals to the column regions, and a free region where the plurality of vertical signal lines are not arranged. Two vertical signal lines adjacent to each other among the plurality of vertical signal lines are arranged so as to sandwich the free region, and the lengths of the two vertical signal lines are substantially the same. Further, each of the plurality of vertical signal lines includes a portion arranged so as to extend in an oblique direction from a Cu—Cu connection (an oblique direction with respect to the direction in which the Cu—Cu connection extends). In the invention described in Japanese Patent Laid-Open No. 2020-78020, it is a requirement that the lengths of two vertical signal lines arranged so as to sandwich the free region are substantially the same. Therefore, the design of a connection path between a vertical signal line arranged in a first substrate and a vertical signal line arranged in a second substrate is largely restricted.

### SUMMARY OF THE INVENTION

The present invention provides a technique advantageous in reducing restrictions on the design of a connection path between a vertical signal line arranged in a first substrate and a vertical signal line arranged in a second substrate.

One of aspects of the present invention provides a photoelectric conversion device that includes a structure in which a first substrate and a second substrate are stacked, wherein the first substrate includes a plurality of pixels, a plurality of first vertical signal lines extending parallel to a first direction, and a plurality of first joints respectively electrically connected to the plurality of first vertical signal lines, and the second substrate includes a plurality of second joints respectively electrically connected to the plurality of first joints, a plurality of second vertical signal lines arranged so as to extend parallel to the first direction, a plurality of column circuits respectively electrically connected to the plurality of second vertical signal lines, a plurality of connecting lines respectively electrically connected to the plurality of second joints, and extending parallel to a second direction orthogonal to the first direction, and an interlayer connection configured to electrically connect each of the plurality of second vertical signal lines and the corresponding connecting line of the plurality of connecting lines.

Further features of the present invention will become apparent from the following description of exemplary embodiments with reference to the attached drawings.

### BRIEF DESCRIPTION OF THE DRAWINGS

FIG. 1 is a view schematically showing the circuit arrangement of a photoelectric conversion device according to an embodiment;

FIG. 2 is a view showing an arrangement example of a pixel;

FIG. 3 is a view schematically showing an arrangement example of a first substrate and a second substrate forming the photoelectric conversion device according to the embodiment;

FIG. 4 is a view illustrating the electrical connection between the first substrate and the second substrate;

FIG. 5 is a view showing an example of the circuit arrangement of a current supply circuit;

FIG. 6 is a view showing a layout example of the current supply circuit;

FIG. 7 is a view showing a comparative example;

FIG. 8 is a view showing a modification:

FIG. 9 is a view for explaining the photoelectric conversion device according to the embodiment;

FIG. 10 is a view showing another modification;

FIG. 11 is a block diagram showing the arrangement of a photoelectric conversion system according to an embodiment;

FIGS. 12A and 12B are views showing the arrangement of a vehicle system and a photoelectric conversion system that is incorporated in the vehicle system and performs image capturing; and

FIG. 13 is a flowchart illustrating an operation of the photoelectric conversion system shown in FIGS. 12A and 12B.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

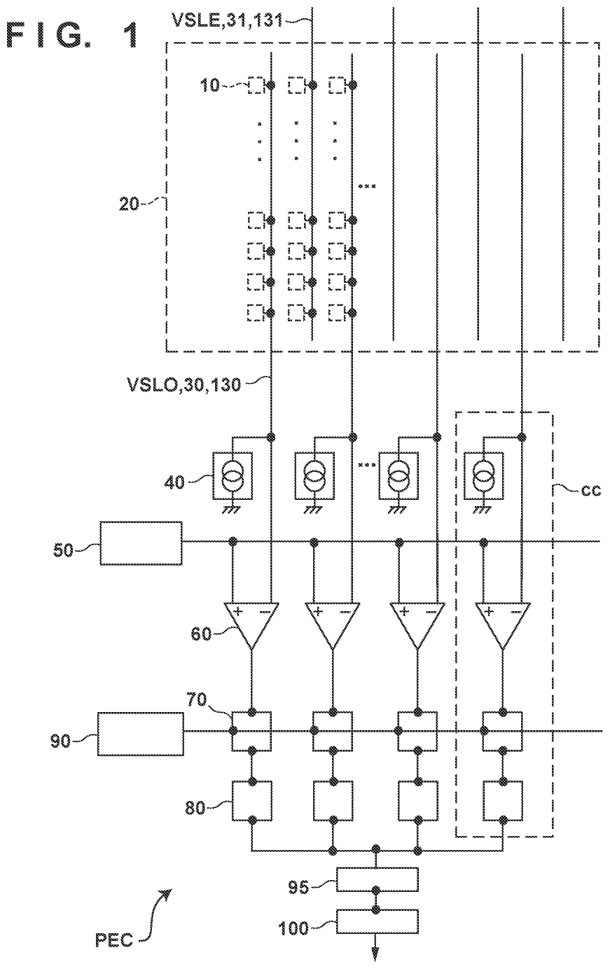

FIG. 1 schematically shows the circuit arrangement of a photoelectric conversion device PEC according to an embodiment. The photoelectric conversion device PEC includes, for example, a pixel array 20 and a plurality of column circuits CC. The pixel array 20 can include a plurality of pixels 10 and a plurality of vertical signal lines. In the example shown in FIG. 1, the plurality of vertical signal lines of the pixel array 20 include vertical signal lines VSLO arranged in odd-numbered columns and vertical signal lines VSLE arranged in even-numbered columns, but this is not intended to limit the invention. Further, in the example shown in FIG. 1, column circuits (the plurality of column circuits CC in FIG. 1) that process signals output via the vertical signal lines VSLO arranged in the odd-numbered columns and column circuits (not shown) that process signals output via the vertical signal lines VSLE arranged in the even-numbered columns can be provided spaced apart from each other. However, this is not intended to limit the invention. The column circuits CC that process signals corresponding to the odd-numbered columns will be described below, but the column circuits that process signals corresponding to the even-numbered columns can have the structure similar to that of the column circuits CC that process signals corresponding to the odd-numbered columns.

The vertical signal line VSLO can include a first vertical signal line 30 arranged in a first substrate, and a second vertical signal line 130 arranged in a second substrate. The first vertical signal line 30 and the second vertical signal line 130 are electrically connected to each other. The photoelectric conversion device PEC can include a structure in which the first substrate and the second substrate are stacked. The photoelectric conversion device PEC may include a structure in which three or more substrates including the first substrate and the second substrate are stacked.

Each column circuit CC can include, for example, a current supply circuit 40 that supplies a current to the vertical signal line VSLO, among a plurality of the vertical signal lines VSLO (the first vertical signal lines 30 and the second vertical signal lines 130), corresponding to this column circuit CC. The column circuit CC may include a comparator 60 that compares the value of a signal supplied from the corresponding vertical signal line VSLO (the first vertical signal line 30 and the second vertical signal line 130) with the value of a ramp signal supplied from a ramp signal generation circuit 50. The ramp signal generation circuit 50 can be arranged in the second substrate. The column circuit CC may include a first memory 70 that holds a count value which is supplied from a counter 90 in accordance with the inversion of the output of the comparator 60. The counter 90 can be arranged in the second substrate. The counter 90 may be commonly provided for the plurality of the vertical signal lines VSLO, or may be individually provided for each of the plurality of the vertical signal lines VSLO. The comparator 60 and the first memory 70 can form an A/D convertor that generates a digital signal corresponding to the signal (analog signal) supplied from the vertical signal line VSLO (the first vertical signal line 30 and the second vertical signal line 130). The column circuit CC may include a second memory 80 that receives the signal (digital signal) held by the first memory 70. It can be understood that the comparator 60, the first memory 70, and the second memory 80 form as an example of a signal processing circuit that processes the signal supplied from the vertical signal line VSLO (the first vertical signal line 30 and the second vertical signal line 130). In place of such the arrangement example, another circuit (for example, an analog amplification circuit or a CDS circuit) may be provided as the signal processing circuit.

The photoelectric conversion device PEC may include a processing circuit 95 that processes signals supplied from a plurality of the second memories 80 or column circuits CC, and an output circuit 100 that outputs the signal generated by processing performed by the processing circuit 95. The processing circuit 95 may be configured to output an image signal generated using the plurality of pixels 10, or may be configured to output a signal obtained by processing the image signal generated using the plurality of pixels 10. The processing circuit 95 and the output circuit 100 can be arranged in the second substrate.

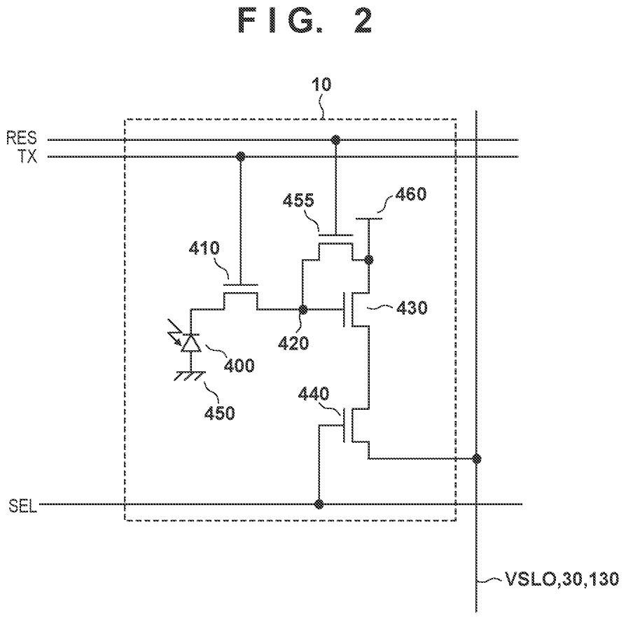

FIG. 2 shows an arrangement example of each pixel 10. The pixel 10 includes at least a photoelectric conversion element 400. The pixel 10 can also include a floating diffusion 420, and a transfer transistor 410 that transfers, to the floating diffusion 420, electric charges generated by the photoelectric conversion element 400. The gate of the transfer transistor 410 can be connected to a transfer control line TX driven by a vertical scanning circuit (not shown). When the voltage of the transfer control line TX is driven to the active level, the transfer transistor 410 can transfer, to the floating diffusion 420, electric charges generated by the photoelectric conversion element 400. The floating diffusion 420 can function as a charge/voltage conversion device that converts the electric charges transferred from the photoelectric conversion element 400 by the transfer transistor 410 into a voltage (potential). The pixel 10 can also include a reset transistor 455 that resets the voltage (potential) of the floating diffusion 420. The gate of the reset transistor 455 can be connected to a reset control line RES driven by the vertical scanning circuit (not shown). When the voltage of the reset control line RES is driven to the active level, the reset transistor 455 can reset the voltage (potential) of the floating diffusion 420. The pixel 10 can also include an amplification transistor 430 that outputs, to the vertical signal line VSLO (the first vertical signal line 30 and the second vertical signal line 130), a signal corresponding the voltage (potential) of the floating diffusion 420. The amplification transistor 430 and the above-descried current supply circuit 40 can form a source follower amplification circuit. The pixel 10 may also include a selection transistor 440 used to set the pixel 10 in a selected state or an unselected state. The gate of the selection transistor 440 can be connected to a selection control line SEL driven by the vertical scanning circuit (not shown). When the voltage of the selection control line SEL is driven to the active level, the selection transistor 440 sets the pixel 10 in the selected state. When the voltage of the selection control line SEL is driven to the inactive level, the selection transistor 440 sets the pixel 10 in the unelected state.

The pixel 10 is not limited to the arrangement described above, and various changes can be made. For example, the pixel 10 may have a function to change the capacitance value of the floating diffusion 420. In other words, the pixel 10 may have a function to change the sensitivity of the floating diffusion 420. The pixel 10 may be formed such that a plurality of the photoelectric conversion elements 400 share the floating diffusion 420. The pixel 10 may be a pixel that can assign such the plurality of the photoelectric conversion elements 400 to one microlens and detect the phase difference.

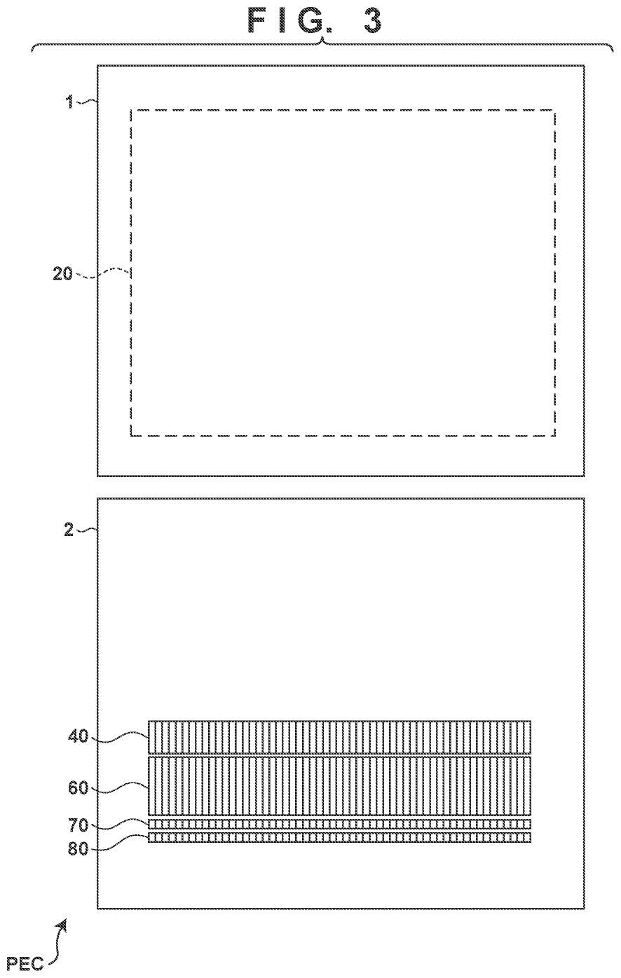

FIG. 3 schematically shows an arrangement example of a first substrate 1 and a second substrate 2 forming the photoelectric conversion device PEC. In FIG. 3, the first substrate 1 and the second substrate 2 are arranged and shown, but the first substrate 1 and the second substrate 2 are stacked on each other. The pixel array 20 including the plurality of pixels 10 is arranged in the first substrate 1, and the plurality of column circuits CC are arranged in the second substrate 2. In the example shown in FIG. 3, each of the plurality of column circuits CC includes the current supply circuit 40, the comparator 60, the first memory 70, and the second memory 80.

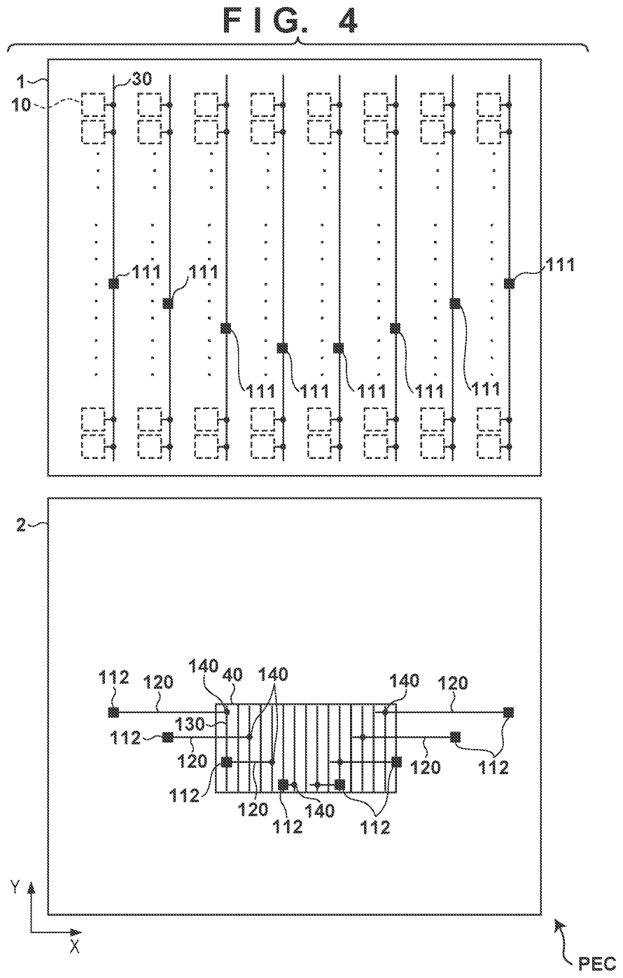

FIG. 4 illustrates the electric connection between the first substrate 1 and the second substrate 2. Here, in FIG. 4, it may be understood that each of the arrangement of the components of the first substrate 1 and the arrangement of the components of the second substrate 2 is the arrangement in the orthogonal projection (planar view) with respect to one main surface of the first substrate 1 (for example, the joint surface between the first substrate 1 and the second substrate 2). For the sake of illustrative simplicity, FIG. 4 shows the pixels 10 for eight columns and the current supply circuits 40 for eight columns. The first substrate 1 can include the plurality of pixels 10, a plurality of the first vertical signal lines 30 extending parallel to the Y direction (first direction), and a plurality of first joints 111 respectively electrically connected to the plurality of the first vertical signal lines 30. The plurality of first joints 111 can be arranged in a minimum rectangular region containing the plurality of pixels 10 forming the pixel array 20, or in a minimum rectangular region containing the pixel array 20.

The second substrate 2 can include a plurality of second joints 112 respectively electrically connected to the plurality of first joints 111, and a plurality of the second vertical signal lines 130 arranged so as to extend parallel to the Y direction (first direction). In an example, the length of each of the plurality of the second vertical signal lines 130 in the direction parallel to the Y direction (first direction) is larger than the array pitch of the plurality of pixels 10 in the direction parallel to the Y direction (first direction). The second substrate 2 can also include the plurality of column circuits CC respectively electrically connected to the plurality of second vertical signal lines 130. The second substrate 2 can also include a plurality of connecting lines 120 respectively electrically connected to the plurality of second joints 112, and extending parallel to the X direction (second direction) orthogonal to the Y direction (first direction). The layer in which the plurality of second vertical signal lines 130 are arranged and the layer in which a plurality of connecting lines 120 are arranged are different layers. The second substrate 2 can also include interlayer connections 140 each of which electrically connects each of the plurality of second vertical signal lines 130 and the corresponding connecting line 120 of the plurality of connecting lines 120. The interlayer connection 140 can be a via plug (conductive member) that electrically connects the second vertical signal line 130 and the corresponding connecting line 120. In this manner, the second joint 112 and the corresponding second vertical signal line 130 can be electrically connected by the connecting line 120 extending parallel to the X direction (second direction) and the interlayer connection 140. This is advantageous in reducing restrictions on the design of the connection path between the vertical signal line 30 arranged in the first substrate 1 and the vertical signal line 130 arranged in the second substrate 2.

In the arrangement illustrated in FIG. 4, at least one connecting line 120 of the plurality of the connecting lines 120 and at least one second vertical signal line 130 of the plurality of second vertical signal lines 130 intersect in different layers. More specifically, in the arrangement illustrated in FIG. 4, four connecting lines 120 of six connecting lines 120 intersect at least one second vertical signal line 130 of the plurality of second vertical signal lines 130 in different layers. Alternatively, in the arrangement illustrated in FIG. 4, at least one connecting line 120 of the plurality of connecting lines 120 can be arranged so as to cross at least one column circuit CC of the plurality of column circuits CC. More specifically, in the arrangement illustrated in FIG. 4, four connecting lines 120 of six connecting lines 120 are arranged so as to cross one column circuit CC of the plurality of column circuits CC (the current supply circuits 40 alone are shown in FIG. 4). The arrangement illustrated in FIG. 4 can reduce the region required to arrange the connection paths between the vertical signal lines 30 arranged in the first substrate 1 and the vertical signal lines 130 arranged in the second substrate 2. This is advantageous in suppressing the cost of the photoelectric conversion device PEC. The arrangement illustrated in FIG. 4 is also advantageous in shortening the connecting path between the vertical signal line 30 arranged in the first substrate 1 and the vertical signal line 130 arranged in the second substrate 2. This is advantageous in increasing the readout speed of reading out signals from the pixel array 20 or the pixels 10. The reason for this will be described later.

As illustrated in FIG. 4, in an orthogonal projection with respect to one main surface of the first substrate 1, at least one connecting line 120 of the plurality of connecting lines 120 can be arranged so as to at least partially overlap at least one column circuit CC of the plurality of column circuits CC (current supply circuits 40). A shield member can be arranged between the at least one connecting line 120 and a node (for example, a specific signal line) of the at least one column circuit CC. Alternatively, in the orthogonal projection with respect to one main surface of the first substrate 1, the plurality of connecting lines 120 can be arranged to at least partially overlap at least one column circuit of the plurality of column circuits CC (current supply circuits 40). A shield member can be arranged between the plurality of connecting lines 120 and a node (for example, a specific signal line) of the at least one column circuit CC). A predetermined potential, for example, a ground potential can be provided to the shield member. The shield member is advantageous in preventing or reducing the signal interference caused by coupling between the connecting line 120 and the node of the column circuit CC overlapping the connecting line 120.

As illustrated in FIG. 4, in the direction parallel to the Y direction (first direction), at least two first joints 111 of the plurality of first joints 111 can be arranged at different positions. The at least two first joints 111 can be arranged on a virtual straight line parallel to a direction intersecting the Y direction (first direction) and the X direction (second direction). Similarly, in the direction parallel to the Y direction (first direction), at least two second joints 112 of the plurality of second joints 112 can be arranged at different positions. The at least two second joints 112 can be arranged on a virtual straight line parallel to a direction intersecting the Y direction (first direction) and the X direction (second direction).

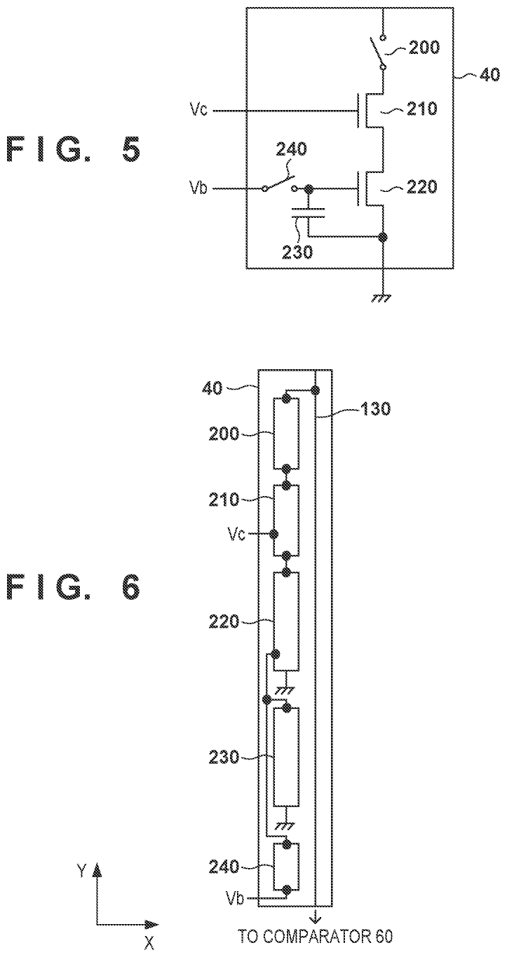

FIG. 5 shows an example of the circuit arrangement of the current supply circuit 40. The current supply circuit 40 can include, for example, a current source transistor 220 that functions as a current source. In addition to this, the current supply circuit 40 may include a holding capacitor 230 that holds a voltage to be supplied to the gate of the current source transistor 220, and a switch 240 that causes the holding capacitor 230 to hold a voltage Vb to be supplied to the gate of the current source transistor 220. The current supply circuit 40 may also include a cascode transistor 210 connected to the current source transistor 220 in series. A voltage Vc can be supplied to the gate of the cascode transistor 210. The current supply circuit 40 may also include a switch 200 connected to the current source transistor 220 in series. The voltage Vb and the voltage Vc can be supplied by a control circuit (not shown).

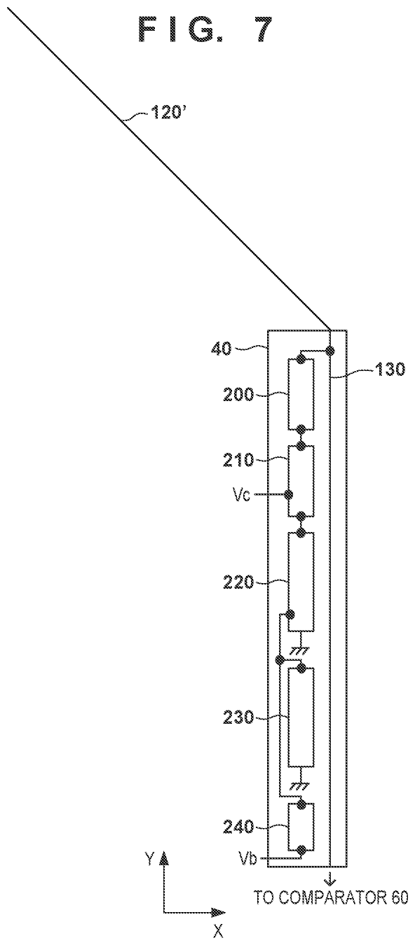

FIG. 6 shows a layout example of the current supply circuit 40. In FIG. 6, it may be understood that the arrangement of the components of the current supply circuit 40 is the arrangement in the orthogonal projection (planar view) with respect to one main surface of the first substrate 1. As illustrated in FIG. 6, each of the plurality of second vertical signal lines 130 can be arranged so as to cross the current supply circuit 40 of the corresponding column circuit CC of the plurality of column circuits CC in the direction parallel to the Y direction (first direction).

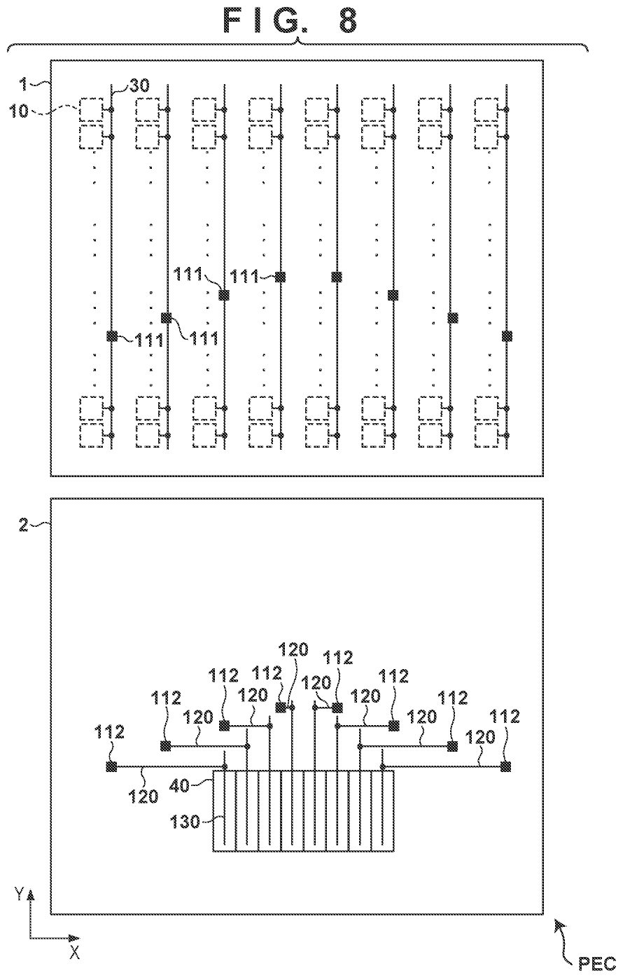

FIG. 7 shows a comparative example. In the comparative example, in accordance with the disclosure of Japanese Patent Laid-Open No. 2020-78020, a connecting line 120′ is arranged so as to extend in an oblique direction, and connected to the second vertical signal line 130. In the comparative example, since the connecting line 120′ extends in the oblique direction, the region required for connecting the first vertical signal line 30 and the second vertical signal line 130 in the second substrate 2 increases, and this can lead to an increase in manufacturing cost of the photoelectric conversion device. If the connecting line 120′ extends in the oblique direction, this can lead to an increase in length of wiring for connecting the first vertical signal line 30 and the second vertical signal line 130, that is, an increase in parasitic resistance and an increase in parasitic capacitance. This can cause a decrease in readout speed.

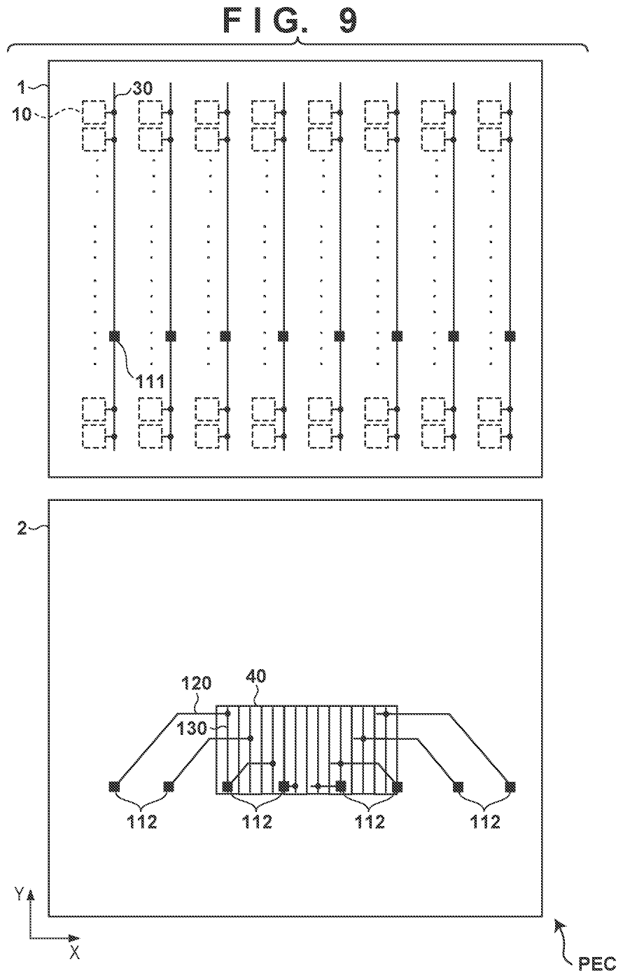

FIG. 8 shows a modification of the above-described embodiment. As illustrated in FIG. 8, in the orthogonal projection with respect to one main surface of the first substrate 1, the plurality of connecting lines 120 can be arranged so as not to overlap any of the plurality of column circuits CC (the current supply circuits 40 alone are shown in FIG. 8). From another point of view, the plurality of connecting lines 120 can be arranged outside a minimum rectangular region containing the plurality of column circuits CC. Alternatively, the plurality of second joints 112 can be arranged outside the minimum rectangular region containing the plurality of column circuits CC. The arrangement as described above is advantageous in preventing or reducing the coupling signal interference between the connecting line 120 and the signal line of the column circuit CC.

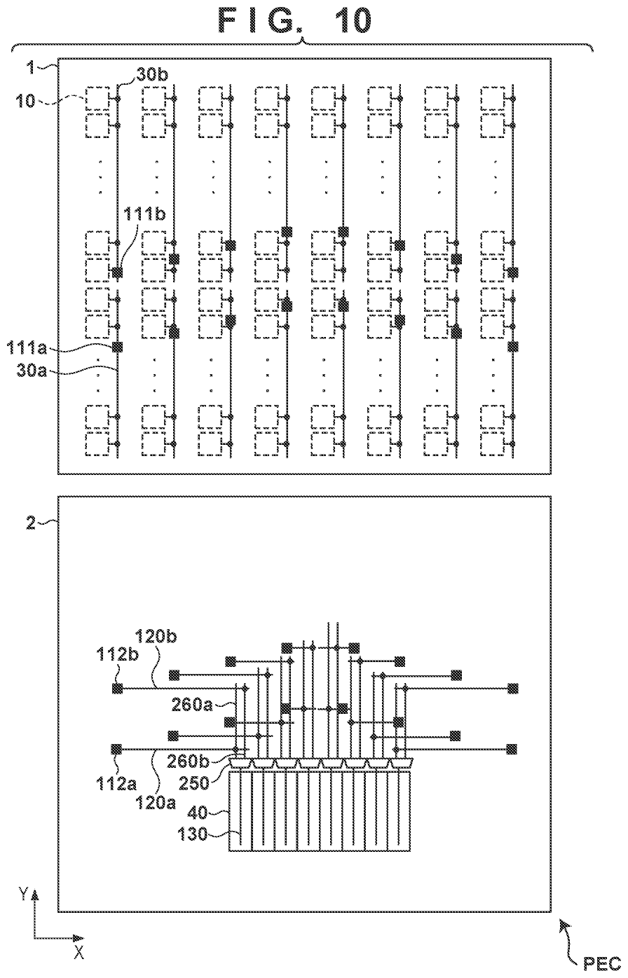

FIG. 9 shows an example in which the plurality of second joints 112 are arranged on a line parallel to the X direction (second direction). From a comparison between the arrangement shown in FIG. 4 and the arrangement shown in FIG. 9, it can be seen that the arrangement shown in FIG. 4 is more advantageous than the arrangement shown in FIG. 9 in shortening the length of the connecting line 120 or increasing the readout speed.

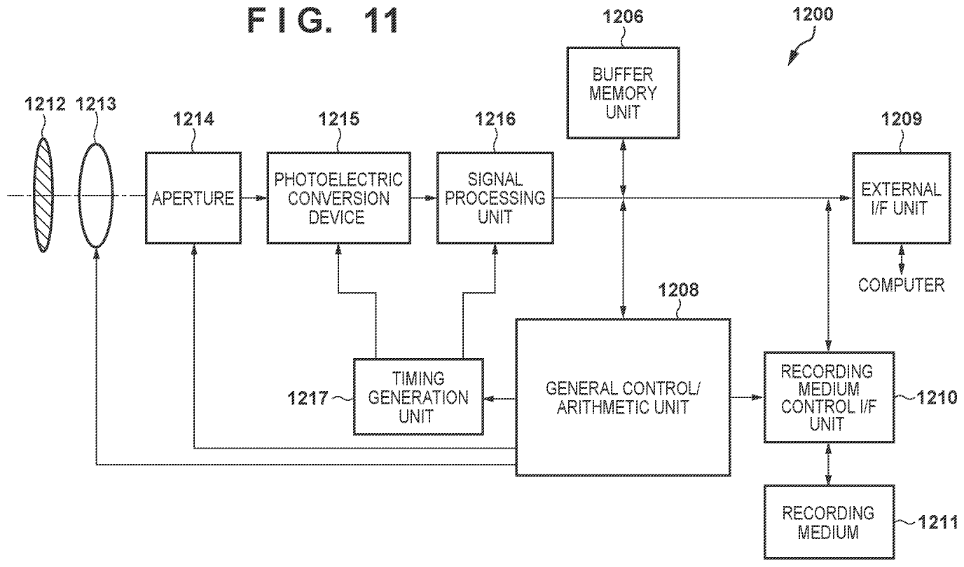

FIG. 10 shows another modification of the above-described embodiment. Matters not described here can follow the above description. This modification achieves an increase in readout speed of reading out signals from the pixels 10 by dividing the vertical signal line into a plurality of partial vertical signal lines. Each of the plurality of first vertical signal lines 30 includes a plurality of first partial vertical signal lines 30a and 30b separated from each other. In other words, each of the plurality of first vertical signal lines 30 is divided into the plurality of first partial vertical signal lines 30a and 30b. The second substrate 2 includes a plurality of second partial vertical signal lines 260a and 260b separated from each other. Each of the plurality of first partial vertical signal lines 30a and the corresponding second partial vertical signal line 260a of the plurality of second partial vertical signal lines 260a are electrically connected via a first joint 111a and a second joint 112a. Each of the plurality of first partial vertical signal lines 30b and the corresponding second partial vertical signal line 260b of the plurality of second partial vertical signal lines 260b are electrically connected via a first joint 111b and a second joint 112b. In other words, a plurality of the first joints 111a and 111b and a plurality of the second joints 112a and 112b are provided such that one first joint and one second joint are assigned to one first partial vertical signal line and one second partial vertical signal line.

Each of the plurality of column circuits CC can include a multiplexer 250 that selects one second partial vertical signal line from the plurality of the second partial vertical signal lines 260a and 260b for the corresponding second vertical signal line 130 of the plurality of second vertical signal lines 130, and connects the selected second partial vertical signal line to the corresponding second vertical signal line 130. As has been described above, the second vertical signal line 130 is connected to the current supply circuit 40. The signal processing circuit that can be formed by the above-described comparator 60, first memory 70, and second memory 80, and the like can operate to process a signal output from the multiplexer 250 via the second vertical signal line 130.

By dividing the first vertical signal line 30 into the plurality of first partial vertical signal lines 30a and 30b, the parasitic capacitance in the signal readout path of the pixel 10 can be reduced, and the readout speed of reading out the signal of the pixel 10 can be increased. Although not shown in FIG. 10, a switch may be provided between each of the first partial vertical signal lines 30a and 30b and a power supply voltage line. The first partial vertical signal line of the first partial vertical signal lines 30a and 30b, that is not used for reading out a signal, can be supplied with the power supply voltage from the power supply voltage line via the switch.

Other modifications will be described below. In the example described above, one first vertical signal line is assigned to each pixel column, but an arrangement may be employed in which multiple first vertical signal lines are assigned to each pixel column so that signals of the pixels in multiple rows can be simultaneously read out. The comparator 60 may be formed to include a switch and a capacitance for an auto zero operation.

An example of a photoelectric conversion system using the photoelectric conversion device according to each embodiment described above will be described below.

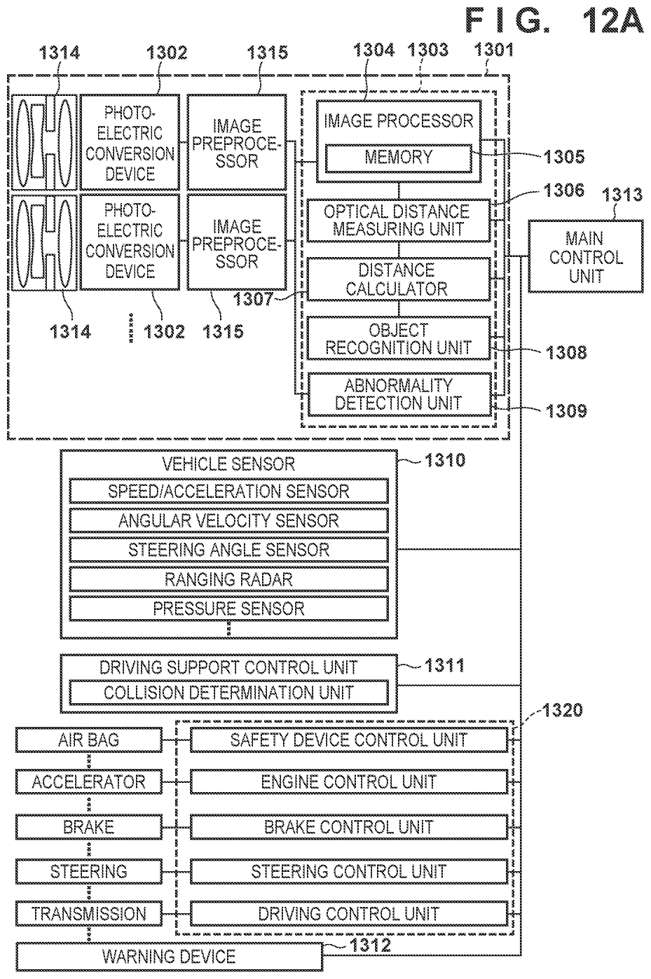

FIG. 11 is a block diagram showing the arrangement of a photoelectric conversion system 1200 according to this embodiment. The photoelectric conversion system 1200 according to this embodiment includes a photoelectric conversion device 1215. Here, any of the photoelectric conversion devices described in the above-described embodiments can be applied to the photoelectric conversion device 1215. The photoelectric conversion system 1200 can be used as, for example, an image capturing system. Practical examples of the image capturing system are a digital still camera, a digital camcorder, and a monitoring camera. FIG. 11 shows an example of a digital still camera as the photoelectric conversion system 1200.

The photoelectric conversion system 1200 shown in FIG. 11 includes the photoelectric conversion device 1215, a lens 1213 for forming an optical image of an object on the photoelectric conversion device 1215, an aperture 1214 for changing the amount of light passing through the lens 1213, and a barrier 1212 for protecting the lens 1213. The lens 1213 and the aperture 1214 form an optical system for concentrating light to the photoelectric conversion device 1215.

The photoelectric conversion system 1200 includes a signal processor 1216 for processing an output signal output from the photoelectric conversion device 1215. The signal processor 1216 performs an operation of signal processing of performing various kinds of correction and compression for an input signal, as needed, thereby outputting the resultant signal. The photoelectric conversion system 1200 further includes a buffer memory unit 1206 for temporarily storing image data and an external interface unit (external I/F unit) 1209 for communicating with an external computer or the like. Furthermore, the photoelectric conversion system 1200 includes a recording medium 1211 such as a semiconductor memory for recording or reading out image capturing data, and a recording medium control interface unit (recording medium control I/F unit) 1210 for performing a recording or reading operation in or from the recording medium 1211. The recording medium 1211 may be incorporated in the photoelectric conversion system 1200 or may be detachable. In addition, communication with the recording medium 1211 from the recording medium control I/F unit 1210 or communication from the external I/F unit 1209 may be performed wirelessly.

Furthermore, the photoelectric conversion system 1200 includes a general control/arithmetic unit 1208 that performs various kinds of arithmetic operations and controls the entire digital still camera, and a timing generation unit 1217 that outputs various kinds of timing signals to the photoelectric conversion device 1215 and the signal processor 1216. Here, the timing signal and the like may be input from the outside, and the photoelectric conversion system 1200 need only include at least the photoelectric conversion device 1215 and the signal processor 1216 that processes an output signal output from the photoelectric conversion device 1215. As described in the fourth embodiment, the timing generation unit 1217 may be incorporated in the photoelectric conversion device. The general control/arithmetic unit 1208 and the timing generation unit 1217 may be configured to perform some or all of the control functions of the photoelectric conversion device 1215.

The photoelectric conversion device 1215 outputs an image signal to the signal processor 1216. The signal processor 1216 performs predetermined signal processing for the image signal output from the photoelectric conversion device 1215 and outputs image data. The signal processor 1216 also generates an image using the image signal. Furthermore, the signal processor 1216 may perform distance measurement calculation for the signal output from the photoelectric conversion device 1215. Note that the signal processor 1216 and the timing generation unit 1217 may be incorporated in the photoelectric conversion device. That is, each of the signal processor 1216 and the timing generation unit 1217 may be provided on a substrate on which pixels are arranged or may be provided on another substrate. An image capturing system capable of acquiring a higher-quality image can be implemented by forming an image capturing system using the photoelectric conversion device of each of the above-described embodiments.

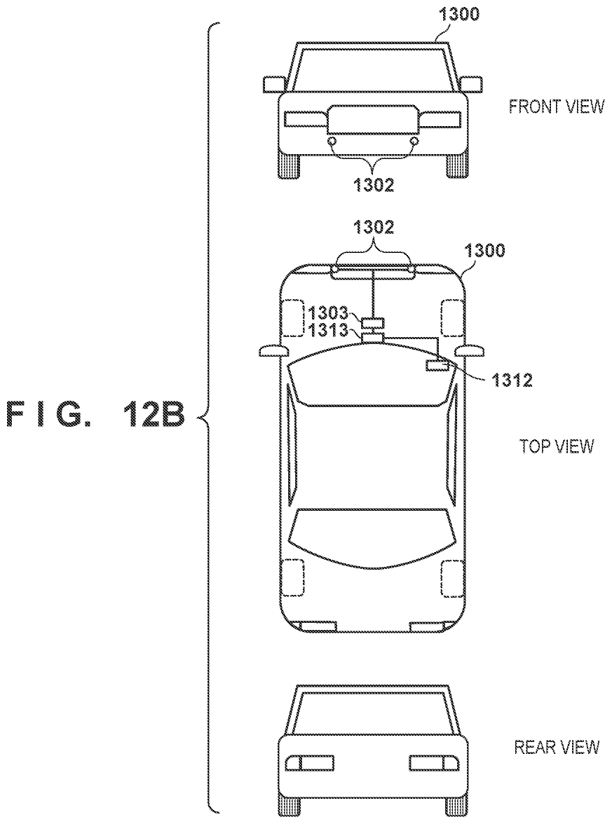

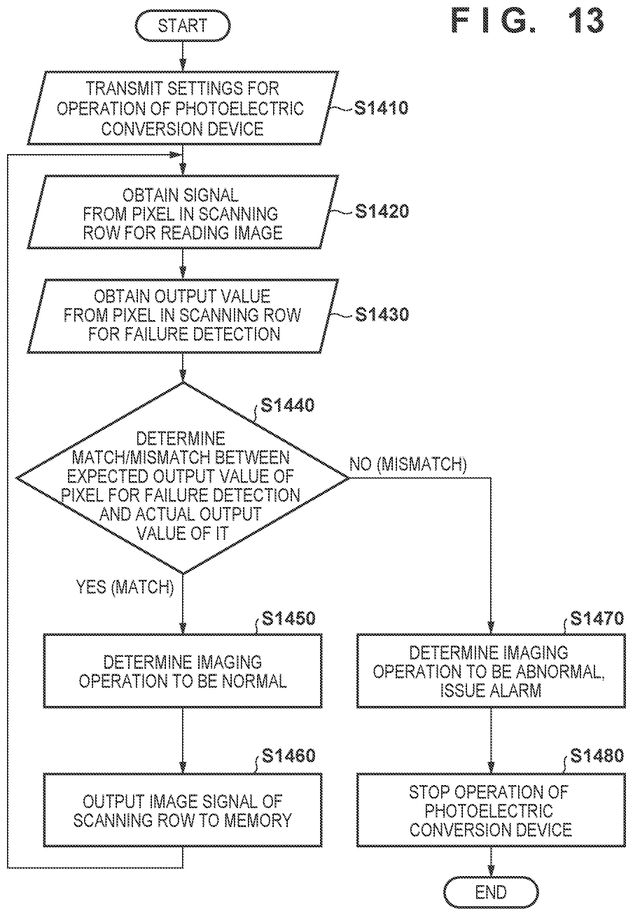

A photoelectric conversion system and a moving body according to this embodiment will be described with reference to FIGS. 12A to 13. FIGS. 12A and 12B are schematic views showing an arrangement example of the photoelectric conversion system and an arrangement example of the moving body, respectively, according to this embodiment. FIG. 13 is a flowchart illustrating an operation of the photoelectric conversion system according to this embodiment. In this embodiment, an example of an in-vehicle camera will be described as the photoelectric conversion system.

FIGS. 12A and 12B show examples of a vehicle system and a photoelectric conversion system that is incorporated in the vehicle system and performs image capturing. A photoelectric conversion system 1301 includes a photoelectric conversion device 1302, an image preprocessor 1315, an integrated circuit 1303, and an optical system 1314. The optical system 1314 forms an optical image of an object on the photoelectric conversion device 1302. The photoelectric conversion device 1302 converts, into an electrical signal, the optical image of the object formed by the optical system 1314. The photoelectric conversion device 1302 is the photoelectric conversion device according to any one of the above-described embodiments. The image preprocessor 1315 performs predetermined signal processing for the signal output from the photoelectric conversion device 1302. The function of the image preprocessor 1315 may be incorporated in the photoelectric conversion device 1302. In the photoelectric conversion system 1301, at least two sets of the optical systems 1314, the photoelectric conversion devices 1302, and the image preprocessors 1315 are arranged, and an output from the image preprocessor 1315 of each set is input to the integrated circuit 1303.

The integrated circuit 1303 is an image capturing system application specific integrated circuit, and includes an image processor 1304 with a memory 1305, an optical distance measurement unit 1306, a distance measurement calculation unit 1307, an object recognition unit 1308, and an abnormality detection unit 1309. The image processor 1304 performs image processing such as development processing and defect correction for the output signal from each image preprocessor 1315. The memory 1305 temporarily stores a captured image, and stores the position of a defect in the captured image. The optical distance measurement unit 1306 performs focusing or distance measurement of an object. The distance measurement calculation unit 1307 calculates distance measurement information from a plurality of image data acquired by the plurality of photoelectric conversion devices 1302. The object recognition unit 1308 recognizes objects such as a vehicle, a road, a road sign, and a person. Upon detecting an abnormality of the photoelectric conversion device 1302, the abnormality detection unit 1309 notifies a main control unit 1313 of the abnormality.

The integrated circuit 1303 may be implemented by dedicated hardware, a software module, or a combination thereof. Alternatively, the integrated circuit 1303 may be implemented by an FPGA (Field Programmable Gate Array), an ASIC (Application Specific Integrated Circuit), or a combination thereof.

The main control unit 1313 comprehensively controls the operations of the photoelectric conversion system 1301, vehicle sensors 1310, a control unit 1320, and the like. A method in which the photoelectric conversion system 1301, the vehicle sensors 1310, and the control unit 1320 each individually include a communication interface and transmit/receive control signals via a communication network (for example, CAN standards) may be adopted without providing the main control unit 1313.

The integrated circuit 1303 has a function of transmitting a control signal or a setting value to each photoelectric conversion device 1302 by receiving the control signal from the main control unit 1313 or by its own control unit.

The photoelectric conversion system 1301 is connected to the vehicle sensors 1310 and can detect the traveling state of the self-vehicle such as the vehicle speed, the yaw rate, and the steering angle, the external environment of the self-vehicle, and the states of other vehicles and obstacles. The vehicle sensors 1310 also serve as a distance information acquisition unit that acquires distance information to a target object. Furthermore, the photoelectric conversion system 1301 is connected to a driving support control unit 1311 that performs various driving support operations such as automatic steering, adaptive cruise control, and anti-collision function. More specifically, with respect to a collision determination function, based on the detection results from the photoelectric conversion system 1301 and the vehicle sensors 1310, a collision with another vehicle or an obstacle is estimated or the presence/absence of a collision is determined. This performs control to avoid a collision when the collision is estimated or activates a safety apparatus at the time of a collision.

Furthermore, the photoelectric conversion system 1301 is also connected to an alarm device 1312 that generates an alarm to the driver based on the determination result of a collision determination unit. For example, if the determination result of the collision determination unit indicates that the possibility of a collision is high, the main control unit 1313 performs vehicle control to avoid a collision or reduce damage by braking, releasing the accelerator pedal, or suppressing the engine output. The alarm device 1312 sounds an alarm such as a sound, displays alarm information on the screen of a display unit such as a car navigation system or a meter panel, applies a vibration to the seat belt or a steering wheel, thereby giving an alarm to the user.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-185153, filed Nov. 12, 2021, which is hereby incorporated by reference herein in its entirety.

What is claimed is:

1. A photoelectric conversion device that includes a structure in which a first substrate and a second substrate are stacked, wherein
the first substrate includes a plurality of pixels, a plurality of first vertical signal lines extending parallel to a first direction, and a plurality of first joints respectively electrically connected to the plurality of first vertical signal lines, and
the second substrate includes a plurality of second joints respectively electrically connected to the plurality of first joints, a plurality of second vertical signal lines arranged so as to extend parallel to the first direction, a plurality of column circuits respectively electrically connected to the plurality of second vertical signal lines, a plurality of connecting lines respectively electrically connected to the plurality of second joints, and extending parallel to a second direction orthogonal to the first direction, and an interlayer connection configured to electrically connect each of the plurality of second vertical signal lines and the corresponding connecting line of the plurality of connecting lines.

2. The device according to claim 1, wherein
at least one connecting line of the plurality of connecting lines and at least one second vertical signal line of the plurality of second vertical signal lines intersect in different layers.

3. The device according to claim 1, wherein
at least one connecting line of the plurality of connecting lines is arranged so as to cross at least one column circuit of the plurality of column circuits.

4. The device according to claim 1, wherein
in an orthogonal projection with respect to one main surface of the first substrate, at least one connecting line of the plurality of connecting lines is arranged so as to at least partially overlap at least one column circuit of the plurality of column circuits.

5. The device according to claim 3, wherein
a shield member is arranged between the at least one connecting line and a node of the at least one column circuit.

6. The device according to claim 1, wherein
in an orthogonal projection with respect to one main surface of the first substrate, the plurality of connecting lines are arranged so as to at least partially overlap at least one column circuit of the plurality of column circuits.

7. The device according to claim 6, wherein
a shield member is arranged between the plurality of connecting lines and a node of the at least one column circuit.

8. The device according to claim 1, wherein
in an orthogonal projection with respect to one main surface of the first substrate, the plurality of connecting lines are arranged so as not to overlap any of the plurality of column circuits.

9. The device according to claim 1, wherein
the plurality of connecting lines are arranged outside a minimum rectangular region containing the plurality of column circuits.

10. The device according to claim 1, wherein
the plurality of second joints are arranged outside a minimum rectangular region containing the plurality of column circuits.

11. The device according to claim 1, wherein
each of the plurality of column circuits includes a current supply circuit configured to supply a current to a corresponding first vertical signal line of the plurality of first vertical signal lines, and
each of the plurality of second vertical signal lines is arranged so as to cross the current supply circuit of a corresponding column circuit of the plurality of column circuits in a direction parallel to the first direction.

12. The device according to claim 11, wherein
each of the plurality of column circuits includes a signal processing circuit configured to process a signal supplied from a corresponding second vertical signal line of the plurality of second vertical signal lines.

13. The device according to claim 12, wherein
the signal processing circuit includes a comparator configured to compare a value of the signal supplied from the second vertical signal line with a value of a ramp signal.

14. The device according to claim 1, wherein
in a direction parallel to the first direction, at least two first joints of the plurality of first joints are arranged at different positions.

15. The device according to claim 14, wherein
the at least two first joints are arranged on a virtual straight line parallel to a direction intersecting the first direction and the second direction.

16. The device according to claim 1, wherein
the plurality of first joints are arranged in a minimum rectangular region containing the plurality of pixels.

17. The device according to claim 1, wherein
each of the plurality of first vertical signal lines includes a plurality of first partial vertical signal lines separated from each other,
the second substrate includes a plurality of second partial vertical signal lines separated from each other, and
the plurality of first joints and the plurality of second joints are provided such that one first joint and one second joint are assigned to one first partial vertical signal line and one second partial vertical signal line.

18. The device according to claim 17, wherein
each of the plurality of column circuits includes a multiplexer configured to select one second partial vertical signal line from the plurality of second partial vertical signal lines for a corresponding second vertical signal line of the plurality of second vertical signal lines, and connect the selected second partial vertical signal line to the corresponding second vertical signal line, and a signal processing circuit configured to process a signal output from the multiplexer.

19. The device according to claim 1, wherein
a length of each of the plurality of second vertical signal lines in a direction parallel to the first direction is larger than an array pitch of the plurality of pixels in the direction parallel to the first direction.

20. A photoelectric conversion system comprising:
a photoelectric conversion device defined in claim 1; and
a signal processor configured to process a signal output by the photoelectric conversion device.

21. A moving body including
a photoelectric conversion device defined in claim 1, and
a distance information acquiring unit configured to acquire, from distance measurement information based on a signal from the photoelectric conversion device, distance information to a target object, the moving body further including
a control unit configured to control the moving body based on the distance information.
